(19) United States
(12) Patent Application Publication
(10) Pub. No.: US 2009/0272990 A1
(43) Pub. Date: Nov. 5, 2009

(54) Light Mixing Apparatus for Light Emitting Diode

(76) Inventors: Ching-cherng Sun, (US); Hsin-ying Ho, (US); Che-chih Hsu, (US); Chng-yu Tsai, (US)

Correspondence Address: HDLS Patent & Trademark Services, P.O. BOX 220746, CHANTILLY, VA, 20153-0746, US

(21) Appl. No.: 12/140,389

(22) Filed: Jun. 17, 2008

(30) Foreign Application Priority Data
May 5, 2008 (TW) 097116535

(51) Int. Cl. H01L 33/00

(52) U.S. Cl. 257/89; 257/98; 257/E33.068

(57) ABSTRACT

A light mixing apparatus of a light emitting diode (LED) is installed on a light emitting surface of the LED. The light emitted from the LED is mixed by a light mixing module of the light mixing apparatus uniformly for adjusting the light output angle. After the angle increases, the light is scattered into a fixed base of the light mixing apparatus, reflected to a containing groove of the light mixing apparatus by a reflecting layer of the fixed base, and guided into the total internal reflection lens of the containing groove. After the total internal reflection lens gathers the light, the light is projected onto a projected surface. If the LED is made of a multi-chip package, the light mixing apparatus can be used for improving the luminance of a light emitted by the LED onto the projected surface and the uniform distribution of the luminance.

### FIELD OF THE INVENTION

The present invention relates to a light mixing apparatus of a light emitting diode, and more particularly to a light mixing apparatus having a light mixing element installed on a total internal reflection (TIR) lens, such that when a light emitting diode is made of multi-chip packages, the light mixing apparatus is provided for uniformly mixing the light emitted from the light emitting diode, and then projecting the light onto a projected surface to enhance the luminance of the projected surface and the uniform distribution of the luminance.

### BACKGROUND OF THE INVENTION

As light emitting diode (LED) is applied to specific products such as mini projectors, automobile light sources and illuminating light source, the luminous flux emitted from the LED generally exceeds thousand of lumens or even tens of thousands of lumens. If the light emitting diode is made of a single-chip package, the luminance of light projected onto a projected surface by the light emitting diode is relatively lower, since the luminous flux of the light emitting diode is lower, such low luminance is insufficient to meet the requirements of this type of products. Therefore, most of the light emitting diodes of this type are made of a multi-chip package, which is also a future development trend. Further, a white light emitting diode can be made of a multi-chip package. In other words, three color (including red, green and blue colors, RGB) light emitting diode chips are packaged into a red, green and blue three-color light emitting diode.

Referring to FIG. 1, a conventional total internal reflection (TIR) lens 12 is generally installed onto the light emitting diode 11 for enhancing the luminance of the light emitting diode 11 on the projected surface. Since the total internal reflection lens 12 can uniformly gather the light energy emitted by the light emitting diode 11 into a smaller range and reduce the light output angle, and then project the light onto the projected surface, therefore the luminance on the projected surface is improved. However, the total internal reflection lens 12 comes with an effect of the lens, and thus after the light emitted from the light emitting diode 11 passes through the total internal reflection lens 12, a chip imaging effect is produced on the projected surface. In other words, the light emitted from a chip in the light emitting diode 11 is focused onto the projected surface by the total internal reflection lens 12, and thus a strong light emitting point is formed at the focus position. In addition, there will be only one strong light emitting point on the projected surface if the light emitting diode 11 is made of a single chip package, and thus the chip imaging effect is not significant. However, there will be many strong light emitting points on the projected surface if the light emitting diode 11 is made of a multi-chip package, and thus the chip imaging effect is significant and causes an uneven distribution of luminance on the projected surface.

Therefore, it is a main purpose of the present invention to develop a new technology to overcome the shortcomings of the conventional emitting diodes 11 made of multi-chip packages causing an uneven distribution of luminance on the projected surface since the total internal reflection lens 12 comes with the effect of a lens.

### SUMMARY OF THE INVENTION

In view of the foregoing shortcomings of the prior art, the inventor of the present invention based on years of experience in the related industry to conduct extensive researches and experiments to overcome the shortcomings of the prior art, and finally developed a light mixing apparatus of a light emitting diode in accordance with the present invention to overcome the shortcomings of the prior art.

Therefore, it is a primary objective of the present invention to provide a light mixing apparatus of a light emitting diode that uses a light mixing apparatus including a light mixing element disposed on a total internal reflection lens to overcome the shortcoming of having an uneven distribution of luminance at a projected surface if the light emitting diode is made of a multi-chip package and installed with a total internal reflection lens. Compared with the prior art, the technology of the present invention gives a better result, when the light emitting diode is made of a multi-chip package.

### BRIEF DESCRIPTION OF THE DRAWING

FIG. 1 is an exploded view of a total internal reflection lens applied to a light emitting diode in accordance with a prior art;

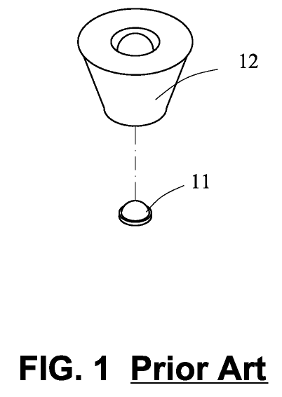

FIG. 2 is an exploded view of a light mixing apparatus applied to a light emitting diode in accordance with a prior art;

FIG. 3 is a side view of a light mixing apparatus applied to a light emitting diode in accordance with a prior art; and

FIG. 4 is a side cross-sectional view of a light mixing apparatus applied to a light emitting diode in accordance with a prior art.

### DETAILED DESCRIPTION OF THE PREFERRED EMBODIMENTS

To make it easier for our examiner to understand the technical measures and operating procedure of the invention, we use a preferred embodiment together with the attached drawing for the detailed description of the invention.

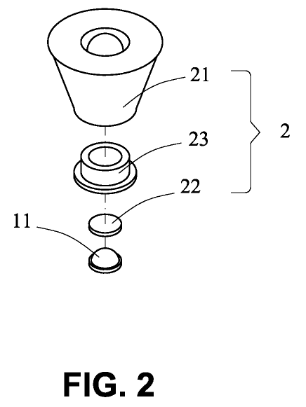

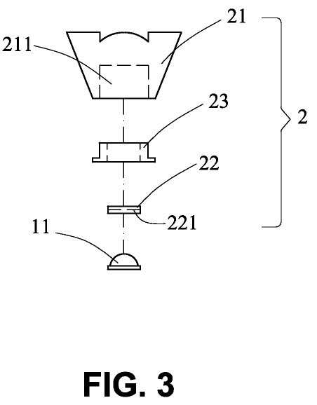

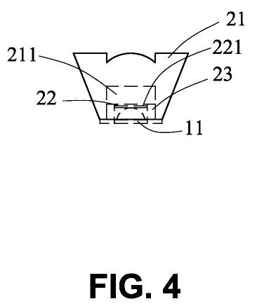

Referring to FIGS. 2 to 4 for a light mixing apparatus of a light emitting diode in accordance with the present invention, the light mixing apparatus 2 comprises: a total internal reflection lens 21 for gathering a light, adjusting an output angle of the light, and projecting the light onto a projected surface (not shown in the figure) after the angle decreases; a containing groove 211 formed in the total internal reflection lens 21 for the containing groove 211 for guiding the light into the total internal reflection lens 2; and a light mixing module 22 disposed in the containing groove 211 and having at least one diffusing element 221, and the light mixing module 22 being provided for mixing the projected light uniformly and adjusting the output angle of the light, such that the light is scattered into the containing groove 211 after the output angle increases, wherein the diffusing element 221 includes but not limited to a diffuser only, and any equivalent element capable of adjusting the light output angle is intended to be covered by the scope of the present invention.

In the present invention, the containing groove 211 further includes a fixed base 23 which is substantially hollow for containing the light mixing module 22, and a reflecting layer disposed on an internal wall of the containing groove 211 for reflecting the light to the containing groove 211.

In a preferred embodiment of the present invention, the light mixing module 22 of the light mixing apparatus 2 is installed on a light emitting surface of a light emitting diode 11 (selected from one of the white light emitting diode and a three color red, green and blue (RGB) light emitting diode of a multi-chip package). The light emitted by the light emitting diode 11 is mixed uniformly by the light mixing module 2, and a light output angle is adjusted, such that after the angle increases, the light is scattered into the fixed base 23, reflected to the containing groove 211 by a reflecting layer in the fixed base 23, guided into the containing groove 211 by the total internal reflection lens 21, and projected onto the projected surface by the total internal reflection lens 21. Since the total internal reflection lens 21 can gather the light, the luminance at the projected surface can be enhanced. Since the light mixing module 22 can mix the lights uniformly, therefore the luminance on the projected surface is distributed uniformly.

Therefore, the present invention has the following advantages over the prior art:

1. As to the practicability, the light mixing apparatus 2 of the invention can be applied to the light emitting diode 11 of the multi-chip package for overcoming the shortcoming of having an uneven distribution of luminance on the projected surface since the total internal reflection lens 12 comes with the effect of a lens. Undoubtedly, the invention is practical and useful.

2. As to the novelty, the total internal reflection lens 21 of the invention is installed separately at the fixed base 22 and the light mixing element 23 and disposed at the light emitting diode 11, and thus the structure is novel. On the other hand, the conventional total internal reflection lens 12 is simply a single component.

3. As to the improvement, the light mixing apparatus 2 of the invention enhances the luminance of the projected surface of the light emitting diode 11 without losing much of the light emitting efficiency, and also maintains a good quality and uniform luminance. Obviously, the invention improves over the prior art.

While the invention has been described by way of example and in terms of a preferred embodiment, it is to be understood that the invention is not limited thereto. To the contrary, it is intended to cover various modifications and similar arrangements and procedures, and the scope of the appended claims therefore should be accorded the broadest interpretation so as to encompass all such modifications and similar arrangements and procedures.

What is claimed is:

1. A light mixing apparatus of a light emitting diode selected from the collection of a multi-chip packaged light emitting diode and a red, green and blue three-color light emitting diode, comprising:
a total internal reflection lens, for gathering a light, adjusting an output angle of the light, and projecting the light onto a projected surface, and the total internal reflection lens further including a containing groove for guiding the light into the total internal reflection lens; and
a light mixing module, disposed in the containing groove, for uniformly mixing the light and adjusting the light output angle, and then scattering the light into the containing groove.

2. The light mixing apparatus of a light emitting diode as recited in claim 1, wherein the containing groove further includes a fixed base which is hollow for containing the light mixing module.

3. The light mixing apparatus of a light emitting diode as recited in claim 2, wherein the fixed base includes a reflecting layer disposed on a hollow internal wall of the fixed base for reflecting a light to the containing groove.

4. The light mixing apparatus of a light emitting diode as recited in claim 3, wherein the light mixing element includes at least one diffusing element.

5. The light mixing apparatus of a light emitting diode as recited in claim 4, wherein the diffusing element is a diffuser.
